(19) United States
(12) Patent Application Publication
(10) Pub. No.: US 2024/0329300 A1
(43) Pub. Date: Oct. 3, 2024

(54) PACKAGE DEVICE AND ELECTRONIC DEVICE

(71) Applicant: Advanced Semiconductor Engineering, Inc., Kaohsiung (TW)

(72) Inventors: Po-I WU, Kaohsiung (TW); Chun-Yen TING, Kaohsiung (TW); Hung-Chun KUO, Kaohsiung (TW); Jung Jui KANG, Kaohsiung (TW); Chiu-Wen LEE, Kaohsiung (TW); Shih-Yuan SUN, Kaohsiung (TW)

(73) Assignee: Advanced Semiconductor Engineering, Inc., Kaohsiung (TW)

(21) Appl. No.: 18/127,624

(22) Filed: Mar. 28, 2023

(51) Int. Cl. G02B 6/12; H04B 10/50

(52) U.S. Cl. CPC G02B 6/12004; H04B 10/501

(57) ABSTRACT

A package device and an electronic device are provided. The package device includes a carrier and a die. The die is disposed over the carrier and has a first surface facing the carrier and a second surface opposite to the first surface. The first surface of the die is configured to electrically connect to the carrier and the second surface of the die is configured to optically connect to the carrier.

### BACKGROUND

### 1. Field of the Disclosure

The present disclosure relates to a package device and an electronic device, and to a semiconductor package structure including a photonic interposer.

### 2. Description of the Related Art

Silicon photonics (SiPh) provide advantages of high-speed communication and low power consumption. An active surface of an integrated circuit (IC) in the SiPh communicates with the other parts (e.g., redistribution layers and/or waveguides) of SiPh. However, an area of the active surface has to be large enough to accommodate all input/output (I/O) units for all signals derived from redistribution layers and/or waveguides. This can impede miniaturization efforts for the SiPh.

### SUMMARY

In some embodiments, a package device includes carrier and a die. The die is disposed over the carrier and has a first surface facing the carrier and a second surface opposite to the first surface. The first surface of the die is configured to electrically connect to the carrier and the second surface of the die is configured to optically connect to the carrier.

In some embodiments, a package device includes a carrier, a die, and a photonic interposer. The die is disposed over the carrier. The photonic interposer is disposed over and optically coupled to the die. The die has a first surface facing away from the carrier. A first portion of the first surface is exposed from the photonic interposer.

In some embodiments, an electronic device includes a component. The component has a first surface and a second surface different from the first surface. The first surface of the component is configured to transmit an electrical signal and the second surface of the component is configured to transmit an optical signal.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 is a top view of a package device according to some embodiments of the present disclosure.

FIG. 1A is a cross-section of a package device according to some embodiments of the present disclosure.

FIG. 2 is a top view of a package device according to some embodiments of the present disclosure.

FIG. 2A is a cross-section of a package device according to some embodiments of the present disclosure.

FIG. 3 is a cross-section of a package device according to some embodiments of the present disclosure.

FIG. 4 is a cross-section of a package device according to some embodiments of the present disclosure.

FIG. 4A is a cross-section of a package device according to some embodiments of the present disclosure.

FIG. 5 is a cross-section of a package device according to some embodiments of the present disclosure.

FIG. 6 is a cross-section of a package device according to some embodiments of the present disclosure.

FIG. 7 is a cross-section of a package device according to some embodiments of the present disclosure.

FIG. 8 is a cross-section of a package device according to some embodiments of the present disclosure.

FIG. 9 is a top view of a package device according to some embodiments of the present disclosure.

FIG. 9A is a cross-section of a package device according to some embodiments of the present disclosure.

FIG. 10 is a top view of a package device according to some embodiments of the present disclosure.

FIG. 10A is a cross-section of a package device according to some embodiments of the present disclosure.

FIG. 11 is a cross-section of a package device according to some embodiments of the present disclosure.

FIG. 12 is a cross-section of a package device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

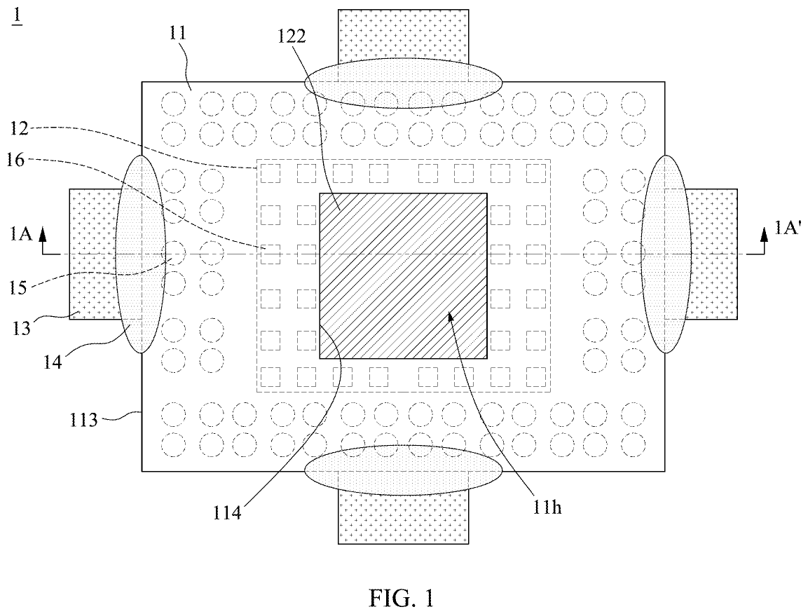

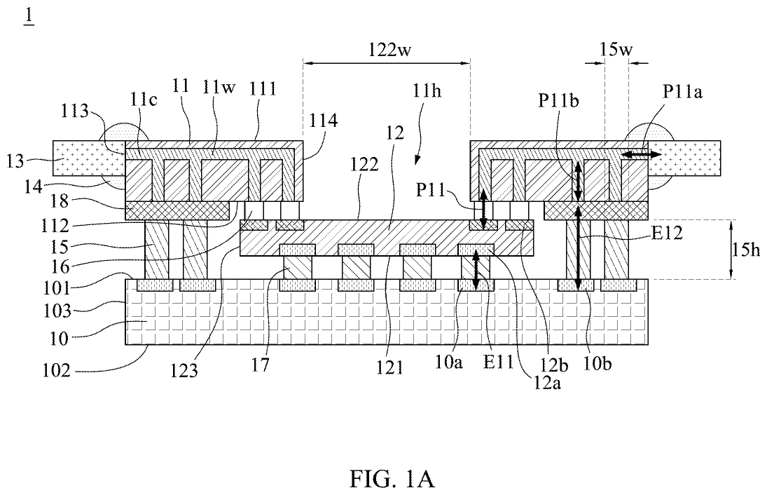

FIG. 1 is a top view of a package device (or an electronic device) 1 according to some embodiments of the present disclosure. FIG. 1A is a cross-section of a package device 1 according to some embodiments of the present disclosure. In some embodiments, FIG. 1A may be a cross-section along line 1A-1A′ of FIG. 1. The package device 1 may include a carrier 10, a photonic interposer 11, a die (or a component) 12, an optical fiber 13, an adhesive material 14, a plurality of conductive pillars 15, a plurality of connection elements 16, a plurality of connection elements 17, and an electro-optic conversion unit 18.

The carrier (or a substrate) 10 may have a surface 101, a surface 102 opposite thereto, and a lateral surface 103 extending therebetween. The surface 101 may face the die 12. The carrier 10 may include a plurality of input/output (I/O) units 10a at the surface 101. The carrier 10 may include a plurality of I/O units 10b at a different location of the surface 101. The I/O units 10a may define a portion 10a (using the same reference numeral for brevity) of the surface 101 of the carrier 10 configured to electrically connect the die 12. The I/O units 10b may define another portion 10b (using the same reference numeral for brevity), different from the portion 10a, of the surface 101 of the carrier 10 configured to electrically connect the conductive pillars 15. The I/O units 10a and 10b may each include a plurality of conductive pads. In some embodiments, the carrier 10 may further include a plurality of conductive pads at the surface 102 of the carrier 10 electrically connecting to an external device. The carrier 10 may include a wiring structure embedded in an insulating layer (not shown). The wiring structure may include a redistribution layer (including a conductive trace, or a conductive via) electrically connecting the I/O units 10a and/or the I/O units 10b.

The I/O units 10a and 10b and the redistribution layer of the wiring structure may each include metal such as copper (Cu), gold (Au), aluminum (Al), titanium (Ti) or the like. The insulating layer of the carrier 10 may include pre-impregnated composite fibers (e.g., a pre-preg material).

The photonic interposer 11 may be disposed over the carrier 10 (e.g., the surface 101), the die 12, the conductive pillar 15, or the electro-optic conversion unit 18. The photonic interposer 11 may have a surface 111 facing away from the die 12 and a surface 112 opposite to the surface 111. The photonic interposer 11 may have a lateral surface (or an exterior lateral surface) 113 extending between the surfaces 111 and 112 of the photonic interposer 11. The photonic interposer 11 may have a lateral surface (or an interior lateral surface) 114 extending between the surfaces 111 and 112 of the photonic interposer 11. The lateral surface 113 is opposite to the lateral surface 114. The lateral surface 113 of the photonic interposer 11 may substantially align with a lateral surface 103 of the carrier 10 perpendicular to the surface 101 of the carrier 10.

The lateral surface 114 of the photonic interposer 11 may be configured to optically couple to the optical fiber 13. The photonic interposer 11 may be configured to transmit an optical signal P11a from the optical fiber 13. The coupling between the photonic interposer 11 and the optical fiber 13 may include grating coupling, edge coupling, or v-groove coupling. In some embodiments, the photonic interposer 11 may include a coupler (or a terminal) 11c (at the surface 113) optically coupled to the optical fiber 13. The optical fiber 13 may be connected or attached to the lateral surface 113 by the adhesive material 14. The adhesive material 14 may partially cover the lateral surface 113 and the surface 111 of the photonic interposer 11. In some embodiments, the coupler 11c may be disposed at the surface (or the upper surface 111) of the photonic interposer 11 and the optical fiber 13 may be optically coupled to the surface 111 (or the coupler 11c) of the photonic interposer 11.

As shown in FIG. 1, the photonic interposer 11 may surround the die 12. The lateral surface 114 of the photonic interposer 11 may define an opening 11h in the middle to expose a portion of the die 12. The photonic interposer 11 may be surrounded by a plurality of optical fibers 13. The photonic interposer 11 may be configured to optically couple to a plurality of optical fibers (four optical fibers 13 as illustrated in FIG. 1) to increase the bandwidth of the optical transmission.

The photonic interposer 11 may be configured to optically couple to the die 12. The photonic interposer 11 may include a waveguide 11w optically coupled to the die 12. The waveguide 11w may include a dielectric material, such as silicon oxide, silicon nitride, or the like. The photonic interposer 11 may be configured to optically couple to the electro-optic conversion unit 18. The waveguide 11w of the photonic interposer 11 may optically couple to the electro-optic conversion unit 18.

The electro-optic conversion unit 18 may be configured to convert an electrical signal E12 from the conductive pillars 15 to an optical signal P11b and vice versa. The electro-optic conversion unit 18 may include a photodiode configured to covert the optical signal P11b from the photonic interposer 11 to the electrical signal E12 which is then transmitted to the conductive pillar 15 or the carrier 10 (e.g., the I/O units 10b). The electro-optic conversion unit 18 may include a laser diode configured to covert the electrical signal E12 from the conductive pillar 15 or the carrier 10 (e.g., the I/O units 10b) to the optical signal P11b which is then transmitted to photonic interposer 11.

The conductive pillars 15 may be disposed over the carrier 10. The conductive pillars 15 may surround the die 12 as illustrated in FIG. 1. The conductive pillars 15 may be disposed below the photonic interposer 11 and/or the electro-optic conversion unit 18. The conductive pillars 15 connects the carrier 10 and the electro-optic conversion unit 18. The conductive pillars 15 may transmit the electrical signal E12 parallel to the lateral surface 123 of the die 12 and over the surface 122 of the die 12. The conductive pillars 15 may be arranged in a multiple-column configuration or an array configuration.

In some embodiments, the electro-optic conversion unit 18 may include a modulator configured to modulate (e.g., amplify) the optical signal or electrical signal received or generated by the electro-optic conversion unit 18.

In some embodiments, the conductive pillars 15, the electro-optic conversion unit 18, and the photonic interposer 11 collectively form a signal path between the carrier 10 (e.g., the I/O units 10b) and the surface 122 of the die 12 (e.g., the I/O units 12b). The electrical signal E12 may transmit through a portion of the signal path and the optical signal P11 (or P11b) communicative with the electrical signal E12 may transmit through another portion of the signal path.

The die 12 may be disposed over the carrier 10. The die 12 may have a surface 121 facing the carrier 10 and a surface 122 opposite to the surface 121 of the die 12. The die 12 may have a lateral surface 123 extending between the surfaces 121 and 122 of the die 12. The surface 121 may be different from the surface 122.

The surface 121 of the die 12 may be configured to electrically connect to the carrier 10 through the connection elements 17. The connection elements 17 may be disposed between the surface 121 of the die 12 and the surface 101 of the carrier 10. The connection elements 17 may include solder balls, controlled collapse chip connection (C4) bumps, a ball grid array (BGA), or a land grid array (LGA). The die 12 may include a plurality of I/O units (or electrical I/O units) 12a disposed at the surface 121 of the die 12. The connection elements 17 may connect the I/O units 12a of the die 12 to the I/O units 10a of the carrier 10. In some embodiments, the die 12 may be configured to transmit an electrical signal E11 to the carrier 10 and vice versa. For example, the surface 121 of the die 12 (or the I/O units 12a) may be configured to transmit the electrical signal E11 to the carrier 10 (or the I/O units 10a) and vice versa.

In some embodiments, the pitch of the I/O units 12a may be different from the I/O units 12b. The pitch of the units 12b may exceed that of the I/O units 12a. A pattern of the I/O units 12a (or the surface 121) and a pattern of the I/O units 12b (or the surface 122) may have different pattern densities. The pattern density of the I/O units 12a (or the surface 121) may be greater than that of the I/O units 12b (or the surface 122). The optical I/O units 12b may have higher bandwidth per unit than the electrical I/O units 12a.

The photonic interposer 11 may be disposed over the surface 122 of the die 12. The connection elements 16 may be disposed between the surface 122 of the die 12 and the surface 112 of the photonic interposer 11. The photonic interposer 11 may expose a portion 122w of the surface 122 of the die 12. The portion 122w of the surface 122 of the die 12 exposed from the photonic interposer 11 may be configured to dissipate heat, e.g., from the die 12. The exposed portion 122w of the surface 122 of the die 12 may increase heat dissipation of the package device 1. If the package device 1 includes a molding material covering the die 12, the exposed portion 122w may be configured to dissipate the heat from the die 12 to the molding material.

The surface 122 of the die 12 may be configured to optically couple to the photonic interposer 11, through the connection elements 16. In some embodiments, the die 12 may include a plurality of I/O units (or optical I/O units) 12b at the surface 122. The I/O units 12b may optically couple to the connection elements 16. The I/O units 12b may optically couple to the waveguide 11w at the surface 113 through the connection elements 16. The I/O units 12b may include a coupling structure, e.g., grating structure.

The surface 122 of the die 12 (or the I/O units 12b) may be configured to transmit an optical signal P11 to the photonic interposer (or the waveguide 11w) and vice versa. The connection elements 16 may include material for guiding the light (e.g., optical signals) therethrough. The connection elements 16 may include a photonic bump configured to optically transmit the light (e.g., optical signals) from the photonic interposer 11 to the die 12 or in an opposite direction. The optical signal P11 may be the optical signal P11a from the optical fiber 13 or the optical signal P11b from the electro-optic conversion unit 18, which is communicative with the electrical signal E12 from the carrier 10. The optical signal P11a carried by the optical fiber 13 may be transmit to the die 12 through the surface 122 of the die.

The die 12 may include a photonic integrated circuit (PIC) configured to process electrical signals (e.g., the electrical signal E11) and optical signals (e.g., the optical signal P11). The die 12 may include a photonic central processing unit (CPU), a microprocessor unit (MPU), a graphics processing unit (GPU), a microcontroller unit (MCU), and an application-specific integrated circuit (ASIC). The die 12 may further include an electro-optic conversion unit (not shown) to convert the receive signals to a compatible type for at least one of the recited processing units, e.g., converting the optical signal to electrical signals for a CPU.

In some cases, an active surface of an IC has to be sufficiently large to accommodate all input/output (I/O) units for all signals derived from redistribution layers and/or waveguides in a Silicon photonics (SiPh). This can impede miniaturization efforts of SiPh and reduce the bandwidth of both signals from the redistribution layers and/or waveguides. In the present disclosure, the die 12 may be configured to electrically connect the carrier 10 through the surface 121 of the die 12 and optically couple to the optical fiber 13 optically through the surface 122 of the die 12. Furthermore, the surface 122 of the die 12 may be configured to transmit or receive an optical signals associated with the carrier 10. In other words, the surface 121 of the die 12 is reserved for electrical connection, thereby the pattern density of the I/O units 12a (or the electrical I/O units) and the bandwidth of the electrical signals can be increased. Similarly, the surface 122 of the die 12 is reserved for optical coupling, thereby the pattern density of the I/O units 12b (or the optical I/O units) and the bandwidth of the optical signals can be increased.

In some embodiments, the package device 1 may include a molding compound to cover or enclose the photonic interposer 11, the die 12, the conductive pillars 15, the connection elements 16 and 17, and the electro-optic conversion unit 18 to reinforce the stiffness of the package device 1. The dielectric layers may not contact the adhesive material 14 to prevent cracking therebetween.

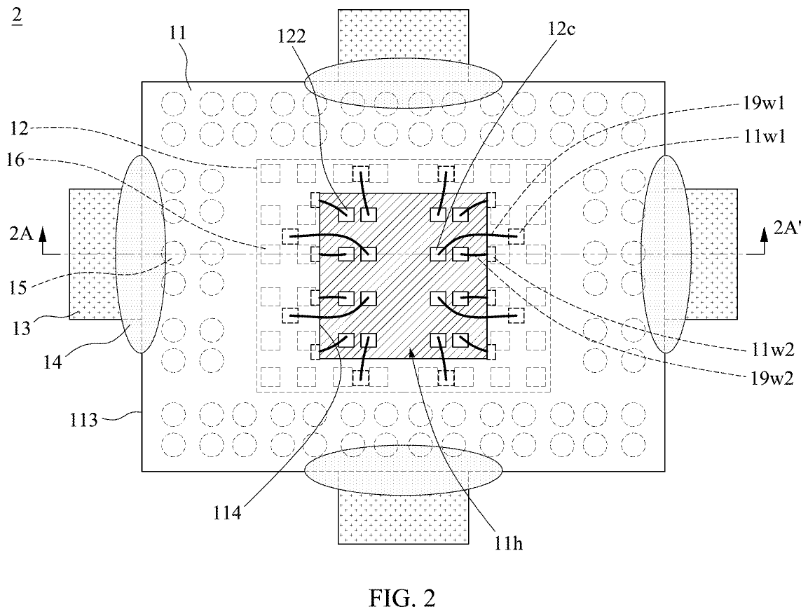

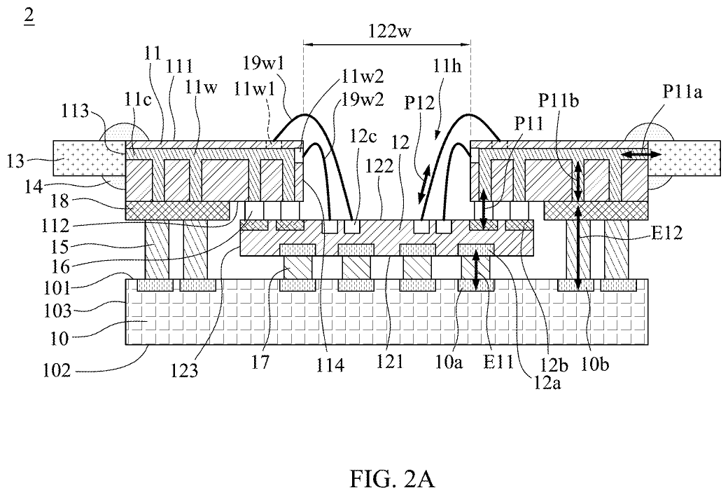

FIG. 2 is a top view of a package device 2 according to some embodiments of the present disclosure. FIG. 2A is a cross-section of a package device 2 according to some embodiments of the present disclosure. In some embodiments, FIG. 2A may be a cross-section along line 2A-A′ in FIG. 2. The package device 2 in FIGS. 2 and 2A is similar to the package device 1 in FIGS. 1 and 1A. Therefore, some detailed descriptions may refer to corresponding preceding paragraphs and are not repeated hereinafter for conciseness, with differences therebetween as follows.

The package device 2 may include a plurality of wires 19w1 and 19w2. The plurality of wires 19w1 and 19w2 may be disposed over the portion 122w of the surface 122 of the die 12. The wires 19w1 and 19w2 may be configured to transmit an optical signal P12 from the photonic interposer 11 to the die 12 and vice versa. The optical signal P12 may be the optical signal P11a from the optical fiber 13 or the optical signal P11b from the electro-optic conversion unit 18, which is communicative with the electrical signal E12 from the carrier 10.

The wires 19w1 and 19w2 may include photonic bonding wires. The wires 19w1 and 19w2 may each include a core of photoresist (e.g., a negative photoresist, SU-8) and a cladding layer of material with a lower refractive index than the core. The wires 19w1 and 19w2 may have a curve shape.

The waveguide 11w of the photonic interposer 11 may include a plurality of terminals 11w1 at the surface 111 and a plurality of terminals 11w2 at the surface 114. The portion 122w of the surface 122 of the die 12 may be configured to optically couple to the die 12 with the photonic interposer 11. The die 12 may include a plurality of I/O units 12c at the exposed portion 122w of the surface 122. The plurality of terminals 11w1 at the surface 111 may optically couple to the plurality of I/O units 12c at the surface 122 through the wires 19w1. The plurality of terminals 11w2 at the surface 114 may optically couple to the plurality of I/O units 12c at the surface 122 through the wires 19w2. The wires 19w1 and 19w2 and/or the I/O units 12c increase bandwidth of the optical signals between the photonic interposer 11 and the die 12.

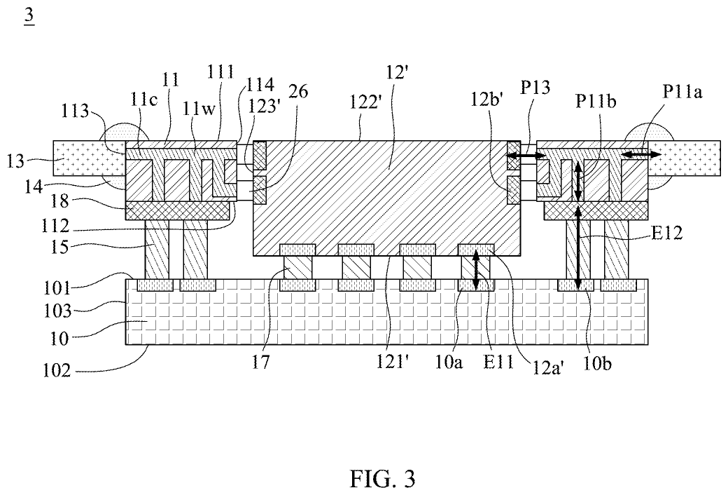

FIG. 3 is a cross-section of a package device 3 according to some embodiments of the present disclosure. The package device 3 in FIG. 3 is similar to the package device 1 in FIG. 1A. Therefore, some detailed descriptions may refer to corresponding preceding paragraphs and are not repeated hereinafter for conciseness, with differences therebetween as follows.

The package device 3 may include a die 12′, rather than the die 12 of the package device 1. The die 12′ may include a plurality of I/O units 12a′ similar to the I/O units 12a of the die 12 of the package device 1. The die 12′ may have a surface 121′ similar to the surface 121 of the die 12 of the package device 1. The die 12′ may have a surface 122′ opposite to the surface 121′ and substantially aligned with the surface 111 of the photonic interposer 11. In some embodiments, the surface 122′ and the surface 111 may be substantially coplanar. In some embodiments, the surface 122′ may be at an elevation higher than the surface 111. The surface 122′ with no I/O units may facilitate heat dissipation from the die 12′.

The die 12′ may include a lateral surface 123′ and a plurality of I/O units 12b′ disposed thereon. The lateral surface 123′ may extend from and be angled with the surface 121′ or 122′. The lateral surface 123′ may connect surfaces 121′ and 122′. The surface 121′ may be different from the surface 123′. The lateral surface 123′ of the die 12′ may face the lateral surface 114 of the photonic interposer 11. The photonic interposer 11 may be closer to the surface 123′ than the surface 121′. The package device 3 may include a plurality of connection elements 26 disposed between the lateral surface 123′ of the die 12′ and the lateral surface 114 of the photonic interposer 11. The optical connection elements 26 may be distributed on along a direction normal to the surface 121′ of the die 12′. The I/O units 12b′ may optically couple to the waveguide 11w through the connection elements 26. The I/O units 12b′ may configured to transmit an optical signal P13 to the photonic interposer 11 through the connection elements 26 and vice versa.

The die 12′ may be configured to electrically connect to the carrier 10 through the surface 121′ of the die 12′ and optically couple to the optical fiber 13 through the surface 123′ of the die 12′. Furthermore, the surface 123′ of the die 12′ may be configured to transmit or receive optical signals associated with the carrier 10. In other words, the surface 121′ of the die 12′ is reserved for electrical connection, thereby the pattern density of the I/O units 12a′ (or the electrical I/O units) and the bandwidth of the electrical signals can be increased. Similarly, the surface 123′ of the die 12′ is reserved for optical coupling, thereby the pattern density of the I/O units 12b′ (or the optical I/O units) and the bandwidth of the optical signals can be increased.

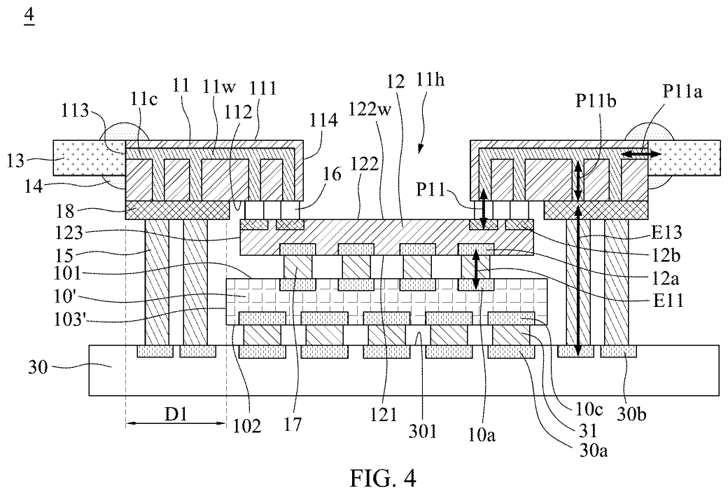

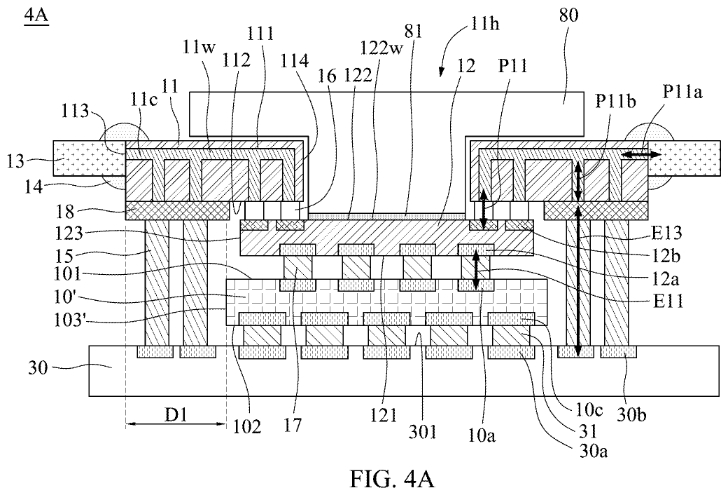

FIG. 4 is a cross-section of a package device according to some embodiments of the present disclosure. The package device 4 in FIG. 4 is similar to the package device 1 in FIG. 1A. Therefore, some detailed descriptions may refer to corresponding preceding paragraphs and are not repeated hereinafter for conciseness, with differences therebetween as follows.

The carrier 10 of the package device 4 has a lateral surface 103′ and an imaginary line extending from the lateral surface 103′ of the carrier 10 is displaced from an imaginary line extending from the lateral surface 113 of the photonic interposer 11 by a distance D1. The package device 4 may include a carrier (or a circuit board) 30 disposed below the carrier 10. The carrier 30 may include a printed circuit board.

The carrier 30 may has a surface 301 facing the carrier 10. The carrier 30 may include a plurality of input/output (I/O) units 30a at the surface 301. The carrier 30 may include a plurality of I/O units 30b at a different portion of the surface 301. The I/O units 30a may define a region 30a (using the same reference numeral for brevity) of the surface 301 of the carrier 30 configured to electrically connect to the carrier 10. The I/O units 30b may define another region 30b (using the same reference numeral for brevity) of the surface 301 of the carrier 30 configured to electrically connect to the conductive pillars 15. The I/O units 30a and 30b may each include a plurality of conductive pads.

The conductive pillars 15 may be disposed over the carrier 30 and connect to the I/O units 30b. The conductive pillars 15 may extend along the lateral surface 123 of the die 12 and the lateral surface 103′ of the carrier 10. The carrier 30 may be configured to transmit an electrical signal E13 to the electro-optic conversion unit 18 through the conductive pillars 15 and vice versa. The electro-optic conversion unit 18 may be configured to convert the electrical signal E13 from the conductive pillars 15 to the optical signal P11b and vice versa.

The carrier 10 may include a plurality of I/O units 10c disposed at the surface 102 of the carrier 10. The plurality of I/O units 10c may be electrically connected to the I/O units 30a of the carrier 30 through a plurality of connection elements 31. The connection elements 31 may include solder balls, controlled collapse chip connection (C4) bumps, a ball grid array (BGA), or a land grid array (LGA). The carrier 10 may be configured to electrically connect the carrier 30 to the die 12.

The die 12 may be configured to electrically connect the carrier 30 through the surface 121 of the die 12 and optically couple to the optical fiber 13 through the surface 122 of the die 12. Furthermore, the surface 122 of the die 12 may be configured to transmit or receive optical signals associated with the carrier 30. In other words, the surface 121 of the die 12 is reserved for electrical connection, thereby the pattern density of the I/O units 12a (or the electrical I/O units) and the bandwidth of the electrical signals can be increased. Similarly, the surface 122 of the die 12 is reserved for optical coupling, thereby the pattern density of the I/O units 12b (or the optical I/O units) and the bandwidth of the optical signals can be increased.

FIG. 4A is a cross-section of a package device 4A according to some embodiments of the present disclosure. The package device 4A in FIG. 4A is similar to the package device 4 in FIG. 4. Therefore, some detailed descriptions may refer to corresponding preceding paragraphs and are not repeated hereinafter for conciseness, with differences therebetween as follows.

The package device 4A may further include a heat sink 80 disposed over the photonic interposer 11. The heat sink 80 may have a portion extending in the opening 11h defined by the photonic interposer 11. The heat sink 80 may be attached to the surface 122 of the die 12 through an adhesive material 81. The adhesive material 81 may include a tin glue. The heat sink 80 may include a metal, which has a relatively high thermal conductivity. The heat sink 80 may be configured to dissipate heat from the package device 4A. In particular, the heat sink 80 may dissipate heat from the portion 122w of the surface 122 of the die 12 through the adhesive material 81. In other words, the portion 122w of the surface 122 of the die 12 may be configured to dissipate heat through the heat sink 80 disposed over the photonic interposer 11.

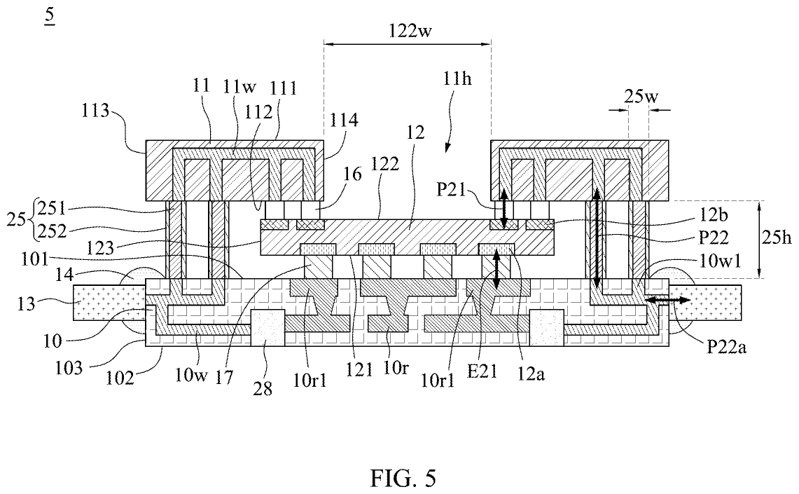

FIG. 5 is a cross-section of a package device 5 according to some embodiments of the present disclosure. The package device 5 may include a carrier 10, a photonic interposer 11, a die 12, an optical fiber 13, an adhesive material 14, a plurality of optical pillars 25, a plurality of connection elements 16, and a plurality of connection elements 17. The photonic interposer 11, the die 12, the connection elements 16, and the connection elements 17 may be similar to the counterparts of the package device 1 in FIGS. 1 and 1A. Therefore, some detailed descriptions may refer to corresponding preceding paragraphs and are not repeated hereinafter for conciseness, with differences therebetween as follows.

The carrier 10 may include a waveguide 10w, an electro-optic conversion unit 28, and a wiring structure 10r. The wiring structure 10r may be electrically connected to the electro-optic conversion unit 28. The wiring structure 10r may be electrically connected to the die 12 (e.g., the I/O units 12a) through the connection elements 17. The waveguide 10w may optically couple to the electro-optic conversion unit 28. The waveguide 10w may optically couple to the optical pillars 25.

The electro-optic conversion unit 28 may be similar to the electro-optic conversion unit 18. In particular, the electro-optic conversion unit 28 may be configured to convert the electrical signal(s) from the wiring structure 10r to the optical signal(s) that will be transmitted to the waveguide 10w and vice versa.

In some embodiments, the die 12 may be configured to transmit the electrical signal E21 to the carrier 10 and vice versa. The wiring structure 10r of the carrier 10 may include a plurality of I/O units 10r1 disposed at the surface 101. The wiring structure 10r (or the I/O units 10r1) may be configured to transmit an electrical signal E21 to the surface 121 of the die (i.e., the I/O units 12a) through the connection elements 17. The I/O units 10r1 may include conductive pads. The wiring structure 10r may include a redistribution layer (including a conductive trace, or a conductive via) electrically connecting the I/O units 10r1.

The lateral surface 103 of the carrier 10 may be configured to optically couple to the optical fiber 13. The carrier 10 may be configured to transmit an optical signal P22a to the optical fiber 13 and vice versa. The coupling between the carrier 10 and the optical fiber 13 may include grating coupling, edge coupling, or v-groove coupling. In some embodiments, the waveguide 10w of the carrier 10 may optically couple to the optical fiber 13. The optical fiber 13 may be connected or attached to the lateral surface 103 by the adhesive material 14. The adhesive material 14 may partially cover the lateral surface 103 and the surface 101 of the carrier 10.

The waveguide 10w of the carrier 10 may include a plurality of I/O units (or optical I/O units) 10w1 disposed at the surface 101 of the carrier 10. The electro-optic conversion unit 28 may be disposed between the plurality of electrical I/O units 10r1 and the optical I/O units 10w1. The I/O units 10w1 may be non-overlapping with a vertical projection of the die 12 on the carrier 10. The I/O units 10w1 may connect to the optical pillars 25. The I/O units 10w of the carrier 10 (or a region of the surface 101) may be configured to transmit an optical signal P22 to the photonic interposer 11 through the optical pillars 25 and vice versa. Since the optical pillars 25 optically couple to the photonic interposer 11 to the carrier 10, no electro-optic conversion therebetween is needed.

In some embodiments, a portion of the surface 101, at which the I/O units 10r1 are disposed, may be configured to transmit the electrical signal E11 and another portion of the surface 101, at which the I/O units 10w1 are disposed, may be configured to transmit the optical signal P22.

In some embodiments, the pitch of the I/O units 10w1 may be different from the I/O units 10r1. The pitch of the units 10w1 may exceed that of the I/O units 10r1. A pattern of the I/O units 10r1 and a pattern of the I/O units 10w1 may have different pattern densities. The pattern density of the I/O units 10r1 may be greater than that of the I/O units 10w1. The optical I/O units 10w1 may have higher bandwidth per unit than the electrical I/O units 10r1.

The photonic interposer 11 may be configured to transmit an optical signal P21 to the I/O units 12b at the surface 122 of the die 12 and vice versa. In some embodiments, the die 12 may be configured to transmit the optical signal P21 to the photonic interposer 11 and vice versa. The optical signal P21 may be communicative with the optical signal P22. The optical signal P21 may be associated with the optical signal P22. The photonic interposer 11 may modulate the optical signal P22 by collimating or adjusting the optical characteristics to produce the optical signal P21. The waveguide 11w may include a beam splitter to split the optical signal P22 into a plurality of optical signals (including the optical signal P21), such that the intensities of the optical signals P21 and P22 may be different but the frequency thereof may be the same. The optical signal P22 may be the optical signal P22a from the optical fiber 13. The optical signal P22 may be the optical signal from the electro-optic conversion unit 28.

The optical pillars 25 may be disposed over the carrier 10. The conductive pillars 25 may surround the die 12. The optical pillars 25 may be disposed below the photonic interposer 11. The optical pillars 25 may be arranged in a multiple-column configuration or an array configuration. The optical pillars 25 may include a core 251 and a cladding layer 252. The optical signal can be transmitted through the core 251. The cladding layer 252 may have a refractive index lower than that of the core 251. The optical pillars 25 may include silica-based glass or plastic. In some embodiments, the core 251 of the optical pillars 25 may be silicon nitride and the cladding layer 252 of the optical pillars 25 silicon oxide.

In the present disclosure, the surface 121 of the die 12 may be configured to electrically connect to the carrier 10 and the surface 122 of the die 12 may be configured to optically connect to the carrier 10. In some embodiments, the I/O units 12a at the surface 121 may electrically connect to the carrier 10 (i.e., the I/O units 10r1). In some embodiments, the I/O units 12b at the surface 122 may be configured to optically couple to the carrier 10 through the photonic interposer 11 and the optical pillars 25, which form an optical transmission path connecting the carrier 10 and the surface 122 of the die 12. The surface 121 of the die 12 is reserved for electrical communication, thereby the pattern density of the I/O units 12a (or the electrical I/O units) and the bandwidth of the electrical signals can be increased. Similarly, the surface 122 of the die 12 is reserved for optical communication, thereby the pattern density of the I/O units 12b (or the optical I/O units) and the bandwidth of the optical signals can be increased.

In an alternative embodiment, the surface 113 of the photonic interposer 11 may substantially align with the surface 123 of the die and the optical pillars 25 may be replaced with a plurality of wires (not shown in FIG. 5). The surface 113 of the photonic interposer 11 as well as the surface 123 of the die 12 may be optically connected to the I/O units 10w1 of the carrier 10 through the plurality of wires.

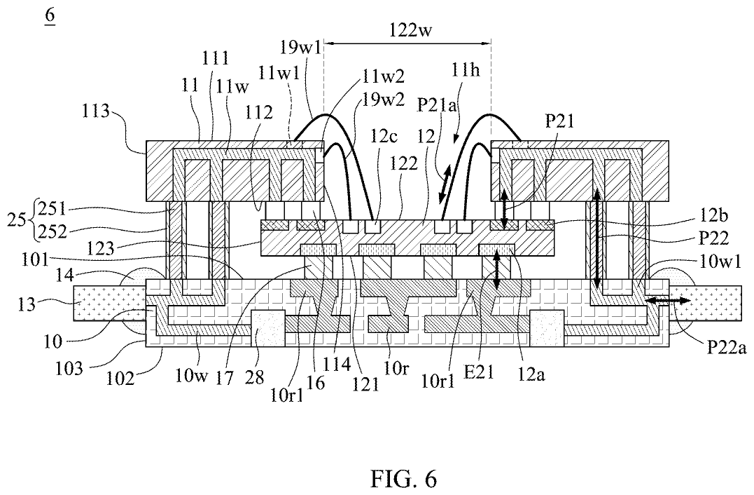

FIG. 6 is a cross-section of a package device 6 according to some embodiments of the present disclosure. The package device 6 in FIG. 6 is similar to the package device 5 in FIG. 5. Therefore, some detailed descriptions may refer to corresponding preceding paragraphs and are not repeated hereinafter for conciseness, with differences therebetween as follows.

The package device 6 may include the plurality of wires 19w1 and 19w2 as illustrated in FIGS. 2 and 2A. The plurality of wires 19w1 and 19w2 may be disposed over the portion 122w of the surface 122 of the die 12. The wires 19w1 and 19w2 may configured to transmit an optical signal P21a between the photonic interposer 11 and the die 12. The optical signal P21a may be the optical signal P22 from the optical fiber 13 (or the carrier 10). The terminals 11w1 and 11w2 of the photonic interposer 11 of the package device 6 may be similar to the counterparts of the photonic interposer 11 of the package device 2. The I/O units 12c of the die 12 of the package device 6 may be similar to the counterparts of the photonic interposer 11 of the package device 2. The wires 19w1 and 19w2 and/or the I/O units 12c increases the bandwidth of the optical signals between the photonic interposer 11 and the die 12.

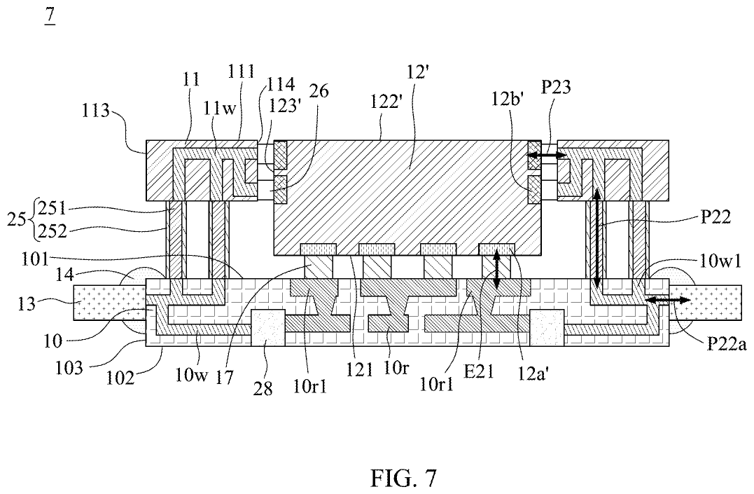

FIG. 7 is a cross-section of a package device 7 according to some embodiments of the present disclosure. The package device 7 in FIG. 7 is similar to the package device 5 in FIG. 5. Therefore, some detailed descriptions may refer to corresponding preceding paragraphs and are not repeated hereinafter for conciseness, with differences therebetween as follows.

The package device 7 may include the die 12′ and the connection elements 26 as illustrated in FIG. 4, and the detailed descriptions may refer to corresponding preceding paragraphs. The exposed surface 122′ with no I/O units may facilitate heat dissipation from the die 12′. The I/O units 12b′ may transmit an optical signal P13 to the photonic interposer 11 through the connection elements 26 and vice versa.

In the present disclosure, the surface 121′ of the die 12′ may be configured to electrically connect to the carrier 10 and the surface 123′ of the die 12′ may be configured to optically couple to the carrier 10. The surface 121′ of the die 12′ is reserved for electrical communication, thereby the pattern density of the I/O units 12a′ (or the electrical I/O units) and the bandwidth of the electrical signals can be increased. Similarly, the surface 123′ of the die 12′ is reserved for optical communication, thereby the pattern density of the I/O units 12b′ (or the optical I/O units) and the bandwidth of the optical signals can be increased.

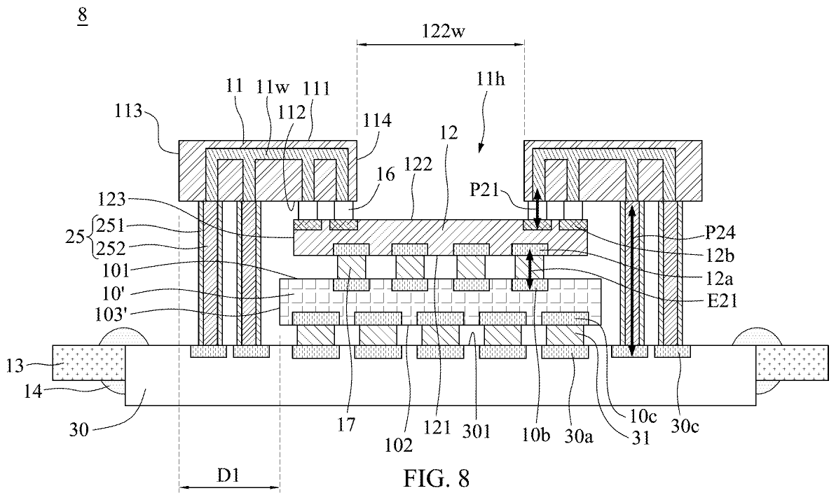

FIG. 8 is a cross-section of a package device 8 according to some embodiments of the present disclosure. The package device 8 in FIG. 8 is similar to the package device 5 in FIG. 5. Therefore, some detailed descriptions may refer to corresponding preceding paragraphs and are not repeated hereinafter for conciseness, with differences therebetween as follows.

The carrier 10 of the package device 8 has a lateral surface 103′ and an imaginary line extending from the lateral surface 103′ of the carrier 10 is displaced from an imaginary line extending from the lateral surface 113 of the photonic interposer 11 by a distance D1. The package device 8 may include the carrier (or a circuit board) 30, which is similar to the carrier 30 of package device 4. For example, the plurality of I/O units 10c may be electrically connected to the I/O units 30a of the carrier 30 through a plurality of connection elements 31. The carrier 30 of the package device 8 may include a plurality of I/O units (or optical I/O units) 30c, rather than the I/O units (or electrical I/O units) 30b at the surface 301. The I/O units 30c may define a region 30c (using the same reference numeral for brevity) of the surface 301 of the carrier 30 configured to optically couple to the optical pillars 25. The I/O units 30c may include a grating structure. The package device 8 may include the optical fiber 13 coupling with the carrier 30 as illustrated in FIG. 5.

The optical pillars 25 may be disposed over the carrier 30 and connect to the I/O units 30c. The optical pillars 25 may extend along the lateral surface 123 of the die 12 and the lateral surface 103′ of the carrier 10. The carrier 30 may be configured to transmit an optical signal P24 to the photonic interposer 11 through the optical pillars 25 and vice versa. The optical signal P21 may be the optical signal P24. The photonic interposer 11 may be configured to transmit the optical signal P21 (or P24) to the die 12.

In the present disclosure, the surface 121 of the die 12 may be configured to electrically connect to the carrier 30 and the surface 122 of the die 12 may be configured to optically couple to the carrier 30. In some embodiments, the I/O units 12a at the surface 121 may be electrically connect to the carrier 30 (i.e., the I/O units 30a). In some embodiments, the I/O units 12b at the surface 122 may be configured to optically couple to the carrier 30 through the photonic interposer 11 and the optical pillars 25, which form an optical transmission path connecting the carrier 30 and the surface 122 of the die 12. The surface 121 of the die 12 is reserved for electrical connection, thereby the pattern density of the I/O units 12a (or the electrical I/O units) and the bandwidth of the electrical signals can be increased. Similarly, the surface 122 of the die 12 is reserved for optical coupling, thereby the pattern density of the I/O units 12b (or the optical I/O units) and the bandwidth of the optical signals can be increased.

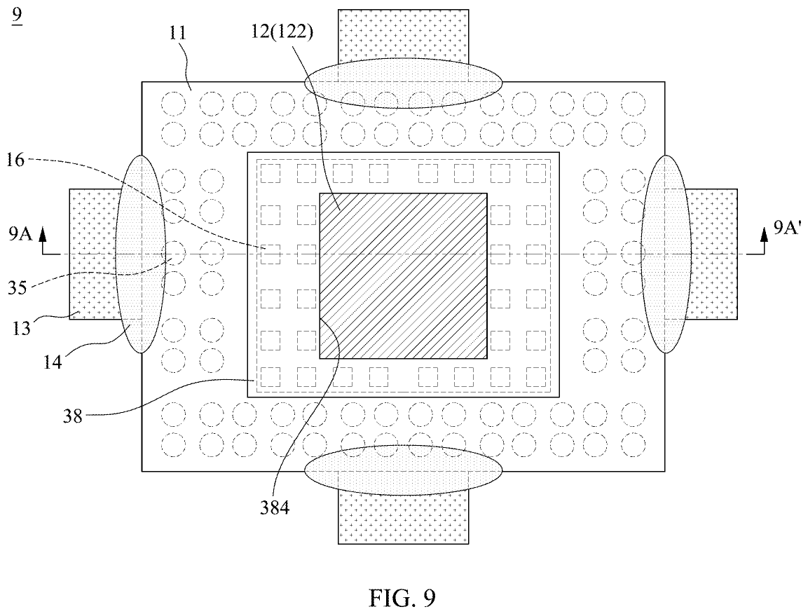

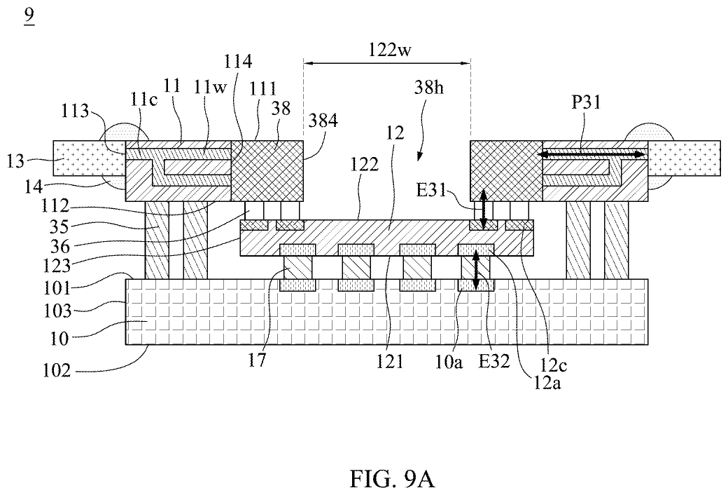

FIG. 9 is a top view of a package device 9 according to some embodiments of the present disclosure. FIG. 9A is a cross-section of a package device 9 according to some embodiments of the present disclosure. In some embodiments, FIG. 9A may be a cross-section along line 9A-9A′ in FIG. 9. The package device 1 may include a carrier 10, a photonic interposer 11, a die 12, an optical fiber 13, an adhesive material 14, a plurality of connection elements 17, a plurality of pillars 35, a plurality of connection elements 36, and an electro-optic conversion unit 38. The carrier 10, the photonic interposer 11, the die 12, and the connection elements 17 may be similar to the counterparts of the package device 1 in FIGS. 1 and 1A. Therefore, some detailed descriptions may refer to corresponding preceding paragraphs and are not repeated hereinafter for conciseness, with differences therebetween as follows.

The die 12 may further include a plurality of I/O units (or electrical I/O units) 12c, rather than the I/O units (or optical I/O units) 12b of the die 12 of the package device 1. The I/O units 12c may be configured to electrically connect the electro-optic conversion unit 38 through connection elements 36. The connection elements 36 may include solder balls, controlled collapse chip connection (C4) bumps, a ball grid array (BGA), or a land grid array (LGA). The I/O units 12c may configured to transmit an electrical signal E31 to the electro-optic conversion unit 38 and vice versa. The I/O units 12a of the die 12 may be configured to transmit an electrical signal E32 to the I/O units 10a of the carrier 10 through the connection elements 17 and vice versa.

The electro-optic conversion unit 38 may be configured to convert the electrical signal E31 to an optical signal P31 and vice versa. The electro-optic conversion unit 38 may be disposed over the surface 122 of the die 12 and adjacent to the photonic interposer 11. The electro-optic conversion unit 38 may have a lateral surface (or an interior lateral surface) 384 to defined an opening 38h. The portion 122w of the surface 122 may be exposed from the opening 38h of the electro-optic conversion unit 38.

The photonic interposer 11 may be configured to optically couple electro-optic conversion unit 38 with the optical fiber 13. The optical fiber 13 may be configured to transmit the optical signal P31 to the electro-optic conversion unit 38 through the photonic interposer 11 and vice versa.

The photonic interposer 11 may be supported by the pillars 35. The pillars 35 may be disposed between the photonic interposer 11 and the carrier 10. The conductive pillars 35 may be arranged in a multiple-column configuration or an array configuration.

In the package device 9, the surface 121 of the die 12 may be configured to electrically connect to the carrier 10 and the surface 122 of the die 12 may be configured to transmit or receive the electrical signal (e.g., the electrical signal E31) associated with the optical signal P31 of the optical fiber 13. The surface 121 of the die 12 is reserved for electrical connection with the carrier 10, thereby the pattern density of the I/O units 12a (or the electrical I/O units) and the bandwidth of the electrical signals can be increased. Similarly, the surface 122 of the die 12 is reserved for the signal transmission associated with the optical fiber 13 and the photonic interposer 11, thereby the pattern density of the I/O units 12c and the bandwidth of the electrical signals can be increased.

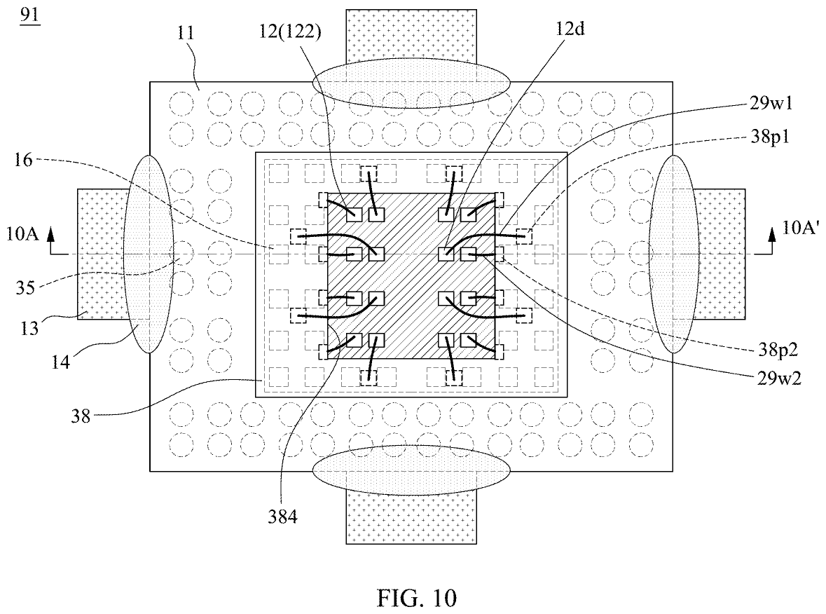

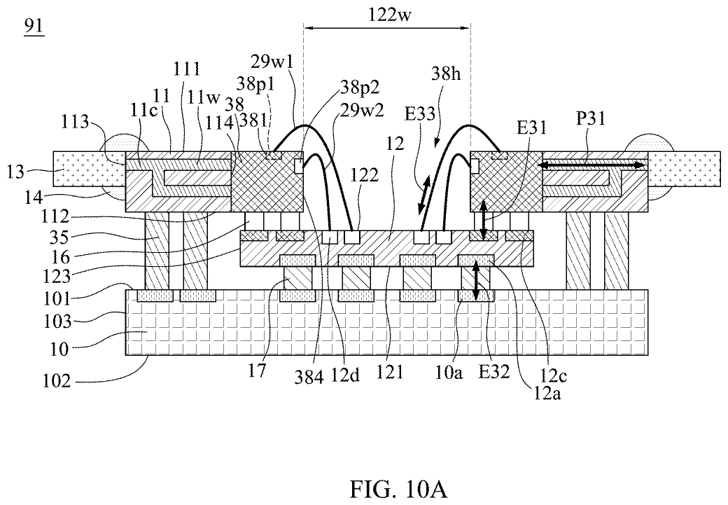

FIG. 10 is a top view of a package device 91 according to some embodiments of the present disclosure. FIG. 10A is a cross-section of a package device 91 according to some embodiments of the present disclosure. FIG. 10A may be a cross-section along line 10A-10A′ in FIG. 10. The package device 91 in FIGS. 10 and 10A is similar to the package device 9 in FIGS. 9 and 9A. Therefore, some detailed descriptions may refer to corresponding preceding paragraphs and are not repeated hereinafter for conciseness, with differences therebetween as follows.

The electro-optic conversion unit 38 may include a plurality of terminals 38p1 at a surface 111 and a plurality of terminals 38p2 at the surface 384. The die 12 may include a plurality of I/O units 12d at the surface 122. The plurality of terminals 38w1 at the surface 381 may be electrically connected with the plurality of I/O units 12d at the surface 122 through the wires 29w1. The plurality of terminals 38p2 at the surface 384 may be electrically connected with the plurality of I/O units 12d at the surface 122 through the wires 29w2. The wires 29w1 and 29w2 and/or the I/O units 12c increases the bandwidth of the electrical signals between the electro-optic conversion unit 38 and the die 12. The wires 29w1 and 29w2 may include bonding wires.

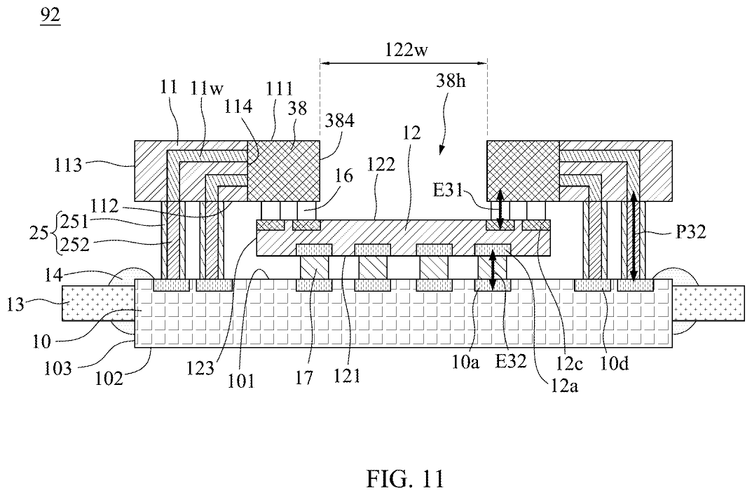

FIG. 11 is a cross-section of a package device 92 according to some embodiments of the present disclosure. The package device 92 in FIG. 11 is similar to the package device 9 in FIG. 9A. Therefore, some detailed descriptions may refer to corresponding preceding paragraphs and are not repeated hereinafter for conciseness, with differences therebetween as follows.

The optical fiber 13 may be attached to the carrier 10. The package device 92 may include the plurality of optical pillars 25 as illustrated in FIG. 5 and the detailed descriptions may refer to corresponding preceding paragraphs. The optical pillars 25 may be configured to optically couple to a plurality of I/O units 10d at the surface 101 of the carrier 10 with the photonic interposer 11. The optical pillars 25 may be configured to transmit an optical signal P32 from the carrier 10 to the photonic interposer 11 and vice versa. Therefore, the optical fiber 13 may optically couple to the photonic interposer 11 through the carrier 10 (a waveguide therein) and the optical pillars 25.

In the package device 92, the surface 121 of the die 12 may be configured to electrically connect to the carrier 10 and the surface 122 of the die 12 may be configured to transmit or receive the electrical signal (e.g., the electrical signal E31) associated with the optical signal P32 from the carrier 10 (or the optical fiber 13). The surface 121 of the die 12 is reserved for electrical connection with the carrier 10, thereby the pattern density of the I/O units 12a (or the electrical I/O units) and the bandwidth of the electrical signals can be increased. Similarly, the surface 122 of the die 12 is reserved for the signal transmission associated with the optical fiber 13 and the photonic interposer 11, thereby the pattern density of the I/O units 12c and the bandwidth of the electrical signals can be increased.

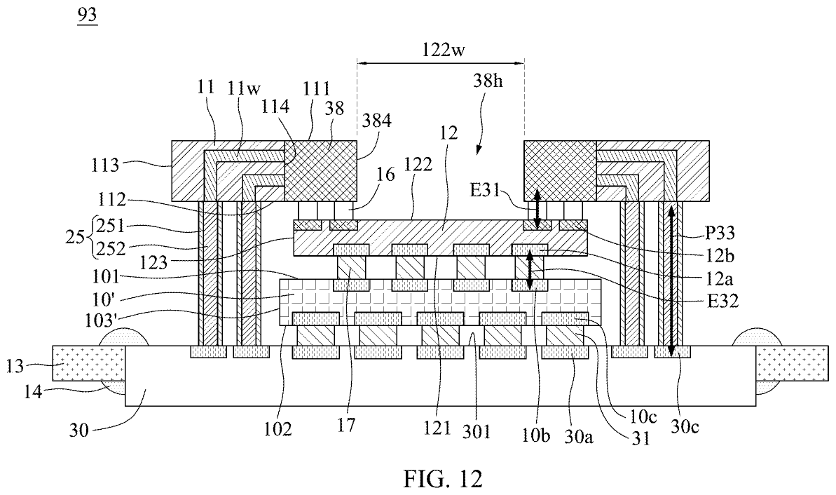

FIG. 12 is a cross-section of a package device 9 according to some embodiments of the present disclosure. The package device 93 in FIG. 12 is similar to the package device 9 in FIG. 9A. Therefore, some detailed descriptions may refer to corresponding preceding paragraphs and are not repeated hereinafter for conciseness, with differences therebetween as follows.

The package device 93 may include the carrier 10, the carrier 30, and the optical pillars 25 as illustrated in FIG. 8 and the detailed descriptions may refer to corresponding preceding paragraphs. The carrier 30 may be configured to transmit an optical signal P33 from the carrier 30 to the photonic interposer 11 through the optical pillars 25 and vice versa. The electro-optic conversion unit 38 may be configured to convert the optical signal P33 to the electrical signal E31 and vice versa.

In the package device 93, the surface 121 of the die 12 may be configured to electrically connect to the carrier 30 and the surface 122 of the die 12 may be configured to transmit or receive the electrical signal (e.g., the electrical signal E31) associated with the optical signal P33 of the carrier 30 (or the optical fiber 13). The surface 121 of the die 12 is reserved for electrical connection with the carrier 30, thereby the pattern density of the I/O units 12a (or the electrical I/O units) and the bandwidth of the electrical signals can be increased. Similarly, the surface 122 of the die 12 is reserved for the signal transmission associated with the optical fiber 13 and the photonic interposer 11, thereby the pattern density of the I/O units 12c and the bandwidth of the electrical signals can be increased.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package device, comprising:
a carrier; and
a die disposed over the carrier and having a first surface facing the carrier and a second surface opposite to the first surface,
wherein the first surface of the die is configured to electrically connect to the carrier and the second surface of the die is configured to optically connect to the carrier.

2. The package device of claim 1, wherein the carrier includes a plurality of electrical I/O units and a plurality of optical I/O units, wherein a pattern of the plurality of electrical I/O units and a pattern of the plurality of optical I/O units have different pattern densities.

3. The package device of claim 2, wherein the optical I/O units are non-overlapping with a vertical projection of the die on the carrier.

4. The package device of claim 1, further comprising a photonic interposer disposed over or adjacent to the second surface of the die, wherein a portion of the second surface of the die is exposed from the photonic interposer.

5. The package device of claim 4, wherein the die further comprises a plurality of optical I/O units at the portion of the second surface of the die.

6. The package device of claim 4, wherein the portion of the second surface of the die exposed from the photonic interposer is configured to dissipate heat.

7. The package device of claim 4, further comprising a plurality of optical pillars disposed between the carrier and the photonic interposer and configured to transmit an optical signal and support the photonic interposer.

8. A package device, comprising:
a carrier;
a die disposed over the carrier; and
a photonic interposer disposed over and optically coupled to the die,
wherein the die has a first surface facing away from the carrier, and a first portion of the first surface is exposed from the photonic interposer.

9. The package device of claim 8, wherein the first portion of the first surface of the die is exposed from an opening defined by the photonic interposer.

10. The package device of claim 8, wherein the first portion of the first surface of the die is configured to optically couple to the die with the photonic interposer and dissipate heat.

11. The package device of claim 10, wherein the die further comprises a second surface facing the carrier, wherein the second surface of the die is configured to at least electrically connect the die with the carrier.

12. The package device of claim 8, wherein the first portion of the first surface of the die is configured to dissipate heat through a heat sink disposed over the photonic interposer.

13. The package device of claim 8, further comprising a plurality of photonic bonding wires connected to a plurality of optical I/O units at the first surface of the die.

14. The package device of claim 13, wherein the plurality of photonic bonding wires are optically coupled to an upper surface or an interior lateral surface of the photonic interposer.

15. An electronic device, comprising:
a component having a first surface and a second surface different from the first surface, wherein the first surface of the component is configured to transmit an electrical signal and the second surface of the component is configured to transmit an optical signal.

16. The electronic device of claim 15, wherein an I/O density of the first surface greater than an I/O density of the second surface.

17. The electronic device of claim 16, wherein the second surface extends from and is angled with the first surface.

18. The electronic device of claim 17, comprising a photonic interposer closer to the second surface than the first surface.

19. The electronic device of claim 18, wherein the photonic interposer comprises a third surface configured to optically couple to the second surface.

20. The electronic device of claim 19, wherein the third surface faces the second surface.
